(19) United States
(12) Patent Application Publication
(10) Pub. No.: US 2007/0034251 A1
(43) Pub. Date: Feb. 15, 2007

(54) Semiconductor elements having zones of reduced oxygen

(75) Inventors: Ralf Jonczyk, Wilmington, DE (US); Scott L. Kendall, Berlin, MD (US); James A. Rand, Landenberg, PA (US)

Correspondence Address: BURR & BROWN, PO BOX 7068, SYRACUSE, NY, 13261-7068, US

(73) Assignee: GE Energy (USA) LLC, Atlanta, GA (US)

(21) Appl. No.: 10/562,518

(22) PCT Filed: Jul. 26, 2004
(86) PCT No.: PCT/US04/23869

§ 371 Date: Jun. 20, 2006

Related U.S. Application Data
(60) Provisional application No. 60/490,125, filed on Jul. 25, 2003.

(51) Int. Cl. H01L 31/00

(52) U.S. Cl. 136/252

(57) ABSTRACT

There is provided a structure comprising semiconductor material, the structure having at least one zone of reduced oxygen concentration, such zone having an interstitial oxygen concentration of not greater than 3×10¹⁷ oxygen atoms/cm³, such zone extending at least 75 microns in depth from a first major surface. There is further provided a photovoltaic cell comprising at least one such structure.

### FIELD OF THE INVENTION

The present invention relates to semiconductor elements having zones of reduced oxygen. In particular, the present invention relates to semiconductor elements having zones of reduced interstitial oxygen, and the use of such semiconductor elements in the manufacture of photovoltaic devices, e.g., solar cells.

### BACKGROUND OF THE INVENTION

Semiconductor elements, e.g., wafers, sheets, plates, ribbons formed of semiconductor material are needed for a variety of applications, and there is an ever-increasing demand for such elements in most, if not all, of such applications.

Currently, silicon is the most commonly used semiconductor material for making semiconductor wafers. Accordingly, where the term “semiconductor” or the term “semiconductor material” is used herein, the discussion in particular relates to silicon. However, those of skill in the art will readily appreciate that in many instances, other semiconductor materials could be substituted for silicon with analogous results.

For example, solar-electric systems employ a semiconductor substrate, typically made of silicon (single crystal or polycrystalline), especially for deployment at or near the surface of the earth. Solar-electric systems have become more and more common, and of greater and greater importance. The use of solar-electric systems is expected to increase, potentially dramatically. As such, improvements in solar-electric technology, even incremental improvements, are of great importance. Although the expression “solar-electric” is used herein, persons of skill in the art will recognize that the discussion applies to all kinds of photovoltaic materials, systems and phenomena.

There is an ongoing need for semiconductor elements which provide improved solar cell collection efficiency. In addition, there is a need for semiconductor elements having low residual stress. In addition, there is a need to produce semiconductor elements at low cost. There is further a need for such semiconductor elements which have improved or outstanding electrical and optical properties.

### BRIEF SUMMARY OF THE INVENTION

In accordance with the present invention, there are provided semiconductor elements which have a zone of reduced oxygen concentration, and which provide improved solar cell performance.

In particular, there is provided a semiconductor element comprising:

a structure comprising at least one semiconductor material, the structure having a first major surface, a second major surface and an edge region, the first major surface being opposite the second major surface, and the edge region comprising at least one surface between the first major surface and the second major surface,

the structure comprising at least one zone of reduced oxygen concentration, the zone of reduced oxygen concentration having an interstitial oxygen concentration of not greater than 3×10¹⁷ oxygen atoms/cm³, the zone of reduced oxygen concentration including the first major surface and all points in the structure which are within 75 microns of the first major surface.

Alternatively, the zone of reduced oxygen concentration includes the first major surface and all points in the structure which are within 100 microns, 125 microns, 150 microns, 175 microns or 200 microns of the first major surface.

The zone of reduced oxygen concentration can include impurities, e.g., 10¹⁵ or more atoms/cm³ of nitrogen, 10¹⁷ or more atoms/cm³ of carbon and/or 10¹⁶ or more atoms/cm³ of transition metal elements. In addition, the grain sizes in the zone of reduced oxygen concentration do not need to be closely controlled. Preferably, the semiconductor element has a thickness defined from the first major surface to the second major surface of about 700 micrometers or less, and preferably, an area of the first major surface is not greater than about 1000 cm².

The present invention is also directed to photovoltaic cells comprising at least one semiconductor element in accordance with the present invention.

The invention may be more fully understood with reference to the accompanying drawings and the following description of the embodiments shown in those drawings. The invention is not limited to the exemplary embodiments and should be recognized as contemplating all modifications within the skill of an ordinary artisan.

### BRIEF DESCRIPTION OF THE DRAWING FIGURES

FIG. 1 is a schematic side view of a structure according to the present invention.

FIG. 2 is a schematic perspective view illustrating an example of a heating/cooling sequence which is suitable for preparing a semiconductor element of the present invention.

FIG. 3 is a sectional view of an embodiment of a semiconductor element in accordance with the present invention, the semiconductor element having a textured surface.

FIG. 4 is a sectional view of an embodiment of a semiconductor element in accordance with the present invention, the semiconductor element having a textured surface.

FIG. 5 is a sectional view depicting an embodiment of a semiconductor element in accordance with the present invention, the semiconductor element having rounded edges.

FIG. 6 is a sectional view of an embodiment of a semiconductor element in accordance with the present invention, the semiconductor element having a p-n junction and a pair of junction isolation ridges.

FIG. 7 is a sectional view of an embodiment of a semiconductor element in accordance with the present invention, the semiconductor element having a p-n junction and a pair of junction isolation ridges.

FIG. 8 is an overhead view of an embodiment of a setter which can be used in preparing a semiconductor element.

FIG. 9 is a sectional view along line IX-IX of FIG. 8.

FIG. 10 is a schematic view showing some of the elements of an apparatus which can be used in preparing a semiconductor element.

FIG. 11 is a sectional view along line XI-XI of FIG. 10.

FIG. 12 is a sectional view along line XII-XII of FIG. 10.

FIG. 13 is a sectional view of an embodiment of a setter which can be used in preparing a semiconductor element.

### DETAILED DESCRIPTION OF THE INVENTION

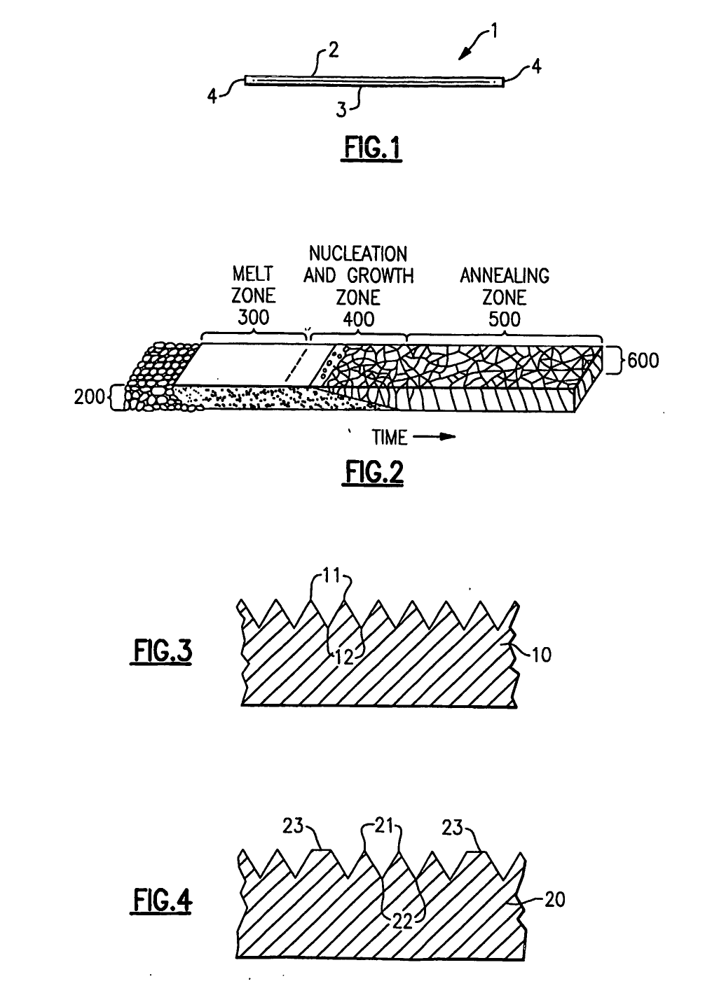

As mentioned above, the present invention provides a semiconductor element comprising a structure which comprises at least one semiconductor material, the structure having a first major surface, a second major surface and an edge region, the first major surface being opposite the second major surface, and the edge region comprising at least one surface between the first major surface and the second major surface. For example, FIG. 1 depicts a structure 1 having a first major surface 2, a second major surface 3 and an edge region 4.

According to the present invention, the semiconductor material can be any semiconducting material. The material out of which semiconductor elements are most commonly formed, especially in the solar-electric art, is silicon. However, those of skill in the art will readily appreciate that the present invention is applicable to other semiconductor materials, e.g., germanium, etc.

The preferred semiconductor material for use in accordance with the present invention is silicon. Where the expression “semiconductor” is used, therefore, silicon is typically the material which is employed and which should be contemplated. However, as noted above, the present invention is applicable to other semiconductor materials, e.g., germanium, etc. Where the specification refers to silicon (or silicon compounds), those of skill in the art can readily appreciate situations where other semiconductor materials (or compounds) function in a way similar to the way silicon (or silicon compounds) function.

In accordance with the present invention, the structure referred to above comprises at least one zone of reduced oxygen concentration, i.e., a zone having an interstitial oxygen concentration of not greater than 3×10¹⁷ oxygen atoms/cm³.

In accordance with one aspect of the present invention, the zone of reduced oxygen concentration includes the first major surface and all points in the structure which are within 75 microns of the first major surface.

In accordance with a further aspect of the present invention, the zone of reduced oxygen concentration includes the first major surface and all points in the structure which are within 100 microns of the first major surface.

In accordance with a further aspect of the present invention, the zone of reduced oxygen concentration includes the first major surface and all points in the structure which are within 125 microns of the first major surface.

In accordance with a further aspect of the present invention, the zone of reduced oxygen concentration includes the first major surface and all points in the structure which are within 150 of the first major surface.

In accordance with a further aspect of the present invention, the zone of reduced oxygen concentration includes the first major surface and all points in the structure which are within 175 microns of the first major surface.

In accordance with a further aspect of the present invention, the zone of reduced oxygen concentration includes the first major surface and all points in the structure which are within 200 microns of the first major surface.

Interstitial oxygen concentration can be measured by any available method, a variety of which (one example is FTIR) are well known to those of skill in the art.

The semiconductor element can have any of a number of features formed therein or on a surface thereof, e.g., one or more holes extending from the first major surface to the second major surface, one or more ridges on at least one of its major surfaces (e.g., a ridge substantially extending around a perimeter of one or both major surfaces), one or more valleys on at least one of its major surfaces (e.g., a ridge substantially extending around a perimeter of one or both major surfaces), one or more cavities on at least one of its major surfaces and/or a rounded contour in part or all of the edge region. In addition, part of all of the edge region can be tapered, i.e., at an angle which is not perpendicular to the first and second major surfaces.

The semiconductor elements according to the present invention can be made by a process as described below. This process is described in U.S. Patent Application No. 60/399,803, filed Jul. 31, 2002 (the entirety of which is hereby incorporated herein by reference), in U.S. Patent Application No. 60/404,506, filed Aug. 19, 2002 and entitled “METHOD AND APPARATUS FOR MANUFACTURING NET SHAPE SEMICONDUCTOR WAFERS” (the entirety of which is hereby incorporated herein by reference) and in PCT International Application No. PCT/US03/23401 filed Jul. 25, 2003 which claims priority from U.S. Patent Application Ser. Nos. 60/399,803 and 60/404,506 and which is entitled “METHOD AND APPARATUS FOR MANUFACTURING NET SHAPE SEMICONDUCTOR WAFERS” (the entirety of which is hereby incorporated herein by reference).

Semiconductor material is deposited into one or more recesses provided on a first side of a setter. The semiconductor material is preferably in the form of a granular powder. A variety of methods for converting semiconductor material, e.g., silicon, from a raw material or from scrap material, into granular powder of a desired purity are well known. For example, there are well known methods for milling semiconductor material, e.g., silicon, to a desired particle size.

The granular semiconductor material is preferably properly sized and of desired purity. The range of size for the granular semiconductor material is preferably between 20 and 1000 micrometers. The upper limit preferably does not exceed the depth of the recess or recesses in the setter. Where the semiconductor material is silicon, the maximum size of the silicon powder is preferably not more than 500 microns. The lower size limit of the particle distribution is dependent on the dynamics of the melting process (described below). In addition, as described below, it may be desirable to provide a “net” structure below the molten silicon. In addition to the silicon material itself, other materials incorporated in a substrate designed to be thermally matched to silicon can be employed as a non-reusable net material. Other materials including fabrics that are woven or non-woven, such as graphite, can be employed as the net. Other granular materials that are partially melted or unmelted, such as silicon carbide can be employed.

If desired, one or more p-dopants or n-dopants can be included in the semiconductor material as it is deposited into the recesses or can be added to the semiconductor material after it has been deposited in the recesses. Typically, p-type conductivity is desired for the base region of the wafer (i.e., usually the majority of the wafer), and inclusion of a p-type dopant is usually advantageous at this stage of the process. Preferred elements for p-type doping include boron, aluminum, gallium and indium. For example, a particularly preferred dopant compound which can be added at this stage is powdered boron silicide, which is preferably mixed with the semiconductor material, e.g., silicon granules, by mechanical mixing. It is also recognized that n-type dopants could be used, and in some instances n-type doping may be preferable to p-type doping.

In addition, one or more additives can be included in the semiconductor material as it is deposited into the recesses or after it has been deposited in the recesses. For example, an additive may be employed to affect the optical bandgap of the wafer (e.g., representative examples of such additives include carbon, which can be added to increase the bandgap, and germanium, which can be added to decrease the optical bandgap). Such changes in the optical bandgap of the wafer material may be deemed to be desirable depending on the spectral output of the incident radiation being employed with a solar cell design.

Furthermore, the material deposited in different regions of the recesses can be closely controlled. For example, the particle size or purity of semiconductor material deposited in one region of a recess, e.g., at the top, can differ from that deposited in another region of a recess, e.g., at the bottom (for instance, it might be desirable to deposit more pure silicon at the top of a recess and less pure silicon at the bottom of a recess in order to produce a wafer in which the top is of better quality and becomes part of the front surface of a solar cell). Another possible feature is to provide different bulk resistivities in different regions of the wafer, e.g., by positioning silicon granules layers in specific regions of the material deposited in the recesses.

The setters each have at least one recess. The one or more recesses can be situated in any desired location(s) in the setter. A plurality of recesses can be provided in each setter. The setter can have at least one recess on each of the major surfaces of the setter. The setter can include a plurality of recesses, e.g., five recesses, on each of a pair of opposite surfaces, the recesses on each surface preferably being arranged in a row, i.e., such that centers of each recess on the first surface define a substantially straight first line, and centers of each recess on the second surface likewise define a different substantially straight second line (preferably parallel to the first line), the setter preferably being symmetrical about a plane passing through both of the first and second lines. By providing recesses on both surfaces of a setter, the setters can be run through the heating/cooling region (described below) with either side facing upward, and can be inverted (between fabrications) in regular intervals (e.g., after each pass through the heating/cooling region) so that warping or other damage due to repeated uneven heating and cooling is eliminated or reduced or reversed. In such an instance, the recesses on opposite surfaces of the setter are preferably mirror images of one another.

The setter can be constructed of generally any material which can maintain its shape during the thermal processing (described below). In addition, the setter preferably does not chemically interact with the semiconductor material to any substantial degree, and preferably does not adhere to the semiconductor material.

Representative examples of materials out of which the setter may be formed include graphite, quartz, refractory boards (e.g. silica and/or alumina), silicon nitride and silicon carbide, with graphite being preferred.

The setters can be machined to provide closely defined surface features, patterns and topography as described below. A machined setter can be machined to as low a resolution as is desired for the structural features desired to be imparted by the setter surfaces to the wafer, e.g., as low as five micrometers or less; as technology advances to efficiently provide even smaller resolution in a machined setter, such resolution can be applied to provide comparably sized structural features in the wafers, as desired.

To assure that the setter does not adhere to the final silicon wafer, a release agent coating is preferably applied to the setter before depositing semiconductor material in the recesses. Preferred release agents include silicon nitride, silicon oxynitride, silica, powdered silicon, alumina, silicon carbide, carbon and combinations thereof. A comparatively inexpensive method for applying a release agent to a setter is to form a liquid slurry containing the release agent, and painting or spraying the slurry on the bare setter, and then preferably drying the slurry before using the setter. The release agent coating may also be applied by any other coating means known in the art. The release agent facilitates separation of the wafer from the setter and preferably permits repeated reuse of the setter.

In a preferred embodiment, the setter material is graphite, and the top surface of the setter is coated with a release agent by painting an aqueous colloidal solution of silicon nitride, and baking the silicon nitride to form a non-wetting, non-adhering oxynitride layer.

The semiconductor material is deposited into the recesses of the setters in any suitable way, a variety of suitable ways being well known, e.g., by metering it from a hopper as the setters pass under the hopper. The semiconductor material is preferably treated by one or more doctor blade, and/or any other suitable method to assist in spreading the semiconductor material more uniformly within the recesses, a variety of spreading methods being well known.

The setters, including the recesses each containing semiconductor material, are then moved through a heating/cooling region including a plurality of temperature-controlled zones, in order to subject the semiconductor material in each recess to a thermal treatment as the semiconductor material in each such recess passes through the different zones.

U.S. Pat. Nos. 6,207,891, 6,111,191, RE 36,156 and U.S. Pat. No. 5,496,416, the entireties of which are each hereby incorporated by reference, each describe examples of heating/cooling regions which would be suitable.

FIG. 2 is a schematic perspective view illustrating a representative example of a suitable melting/solidification sequence. FIG. 2 depicts stages through which a vertically defined section of a single wafer being fabricated passes, the distance from the left being representative of the length of time elapsed (i.e., movement from left to right in FIG. 2 represents only passage of time).

In the heating/cooling sequence depicted in FIG. 2, the semiconductor material is subjected to an aggressive melt. The expression “aggressive melt” encompasses treatments in which, for a period of time (e.g., 1 or 2 seconds, 15 seconds or more, or 30 seconds or more), the portion of the semiconductor material targeted to be denuded in a recess is molten (i.e., in the liquid phase) in the presence of the nucleation layer on the first major surface (as described in U.S. Pat. No. 6,111,191 and incorporated herein by reference).

In carrying out an aggressive melt, it is preferred that care be taken to avoid large temperature spikes which may occur upon the entirety of the semiconductor material becoming molten. That is, due to the relatively large heat of fusion of semiconductor materials (e.g., silicon), a significant rate of heat transfer, without significant temperature increase, can be absorbed by the semiconductor material as it is being converted from solid phase to liquid phase-when all of the semiconductor material has become converted to liquid phase, such significant heat transfer rate can rapidly increase the temperature of the semiconductor material. The effects of such potential temperature increase are exacerbated by the fact that the materials out of which the setters are made tend to have a relatively high rate (in comparison to the semiconductor material) of heat absorption. For example, radiant heat is typically used to heat the semiconductor material, and the semiconductor material, e.g., silicon, may have a much lower rate of heat absorption than the material out of which the setter is made, e.g., graphite. In the event that the setter reaches a temperature which is significantly higher than the melting temperature of the semiconductor material, the quality of the finished wafer tends to be severely degraded. Accordingly, during the aggressive melt stage, it is generally necessary to withdraw heat from the bottom of the setters. Persons of skill in the art are readily familiar with a variety of ways to effect such heat withdrawal, e.g., contact with or proximity to conduit through which cooling fluid is passed. After the aggressive melt, the semiconductor material is then further processed to form the wafer, e.g., by subjecting to a top-down solidification as described below.

Aggressive melts result in production of a zone of reduced oxygen concentration, the zone of reduced oxygen concentration having an interstitial oxygen concentration of not greater than 3×10¹⁷ oxygen atoms/cm³, the zone of reduced oxygen concentration extending from the surface opposite the surface formed in contact with the setter for a depth of at least 75 microns. The zone of reduced oxygen concentration can extend deeper into the wafer, e.g., to a depth of 100 microns, 125 microns, 150, microns, 175 microns or 200 or more microns, especially where there are provided longer periods of time during which the entirety of the semiconductor material are molten.

The present invention is predicated on the applicant's discovery that the combination of an aggressive melt regimen, the presence of a nucleation layer on the first major surface, and the subsequent heat treatment of the solidified material, produces a zone of reduced interstitial oxygen concentration in the solidified wafer. After a subsequent heat treatment, precipitates are formed in the non-denuded areas of the wafer where oxygen concentrations are above solubility levels.

The precipitates that form in the non-denuded zone areas may advantageously serve as preferential gettering sites for transition metal impurities, as is well known in the industry. Transition metal impurities may significantly limit solar cell device performance when present at, or near the first major surface of the device. By limiting oxygen precipitates to the non-illuminated side of the resulting solar cell device (near the second major surface), an ensuing heat treatment step will result in transition metals being drawn away from the more critical denuded zone area, and sequestered at the oxygen precipitates.

The heat treatment may comprise a thermal process reaching a peak temperature in the range of 800-1100° C. in the presence of oxygen, nitrogen, or other atmospheres. The heating rate, cooling rates, and time at peak temperature, may impact the oxygen precipitate density and size. A preferred embodiment is a treatment at 1100° C. in an muffle furnace in an atmosphere of nitrogen with a heating rate of 10° C./min and cooling rate of 10° C./min.

These phenomena, which result from an aggressive melt, a cap layer, and a subsequent heat treatment, were unexpected and counter intuitive to conventional experience in forming silicon sheets by a melting process. Further, the applicants have exploited this finding to tailor the aggressive melt process in order to control the thickness and position of the oxygen-denuded zone. Moreover, the realization and control of a reduced oxygen zone can be developed to considerable advantage in producing silicon wafers.

The conventional practice of casting silicon sheets or wafers indicated that the extent to which the silicon charge was molten at a particular time, had no predictable consequence on the concentration of oxygen in the final silicon wafer product. Therefore, in was surprising in our experimental studies that that use of an aggressive melt protocol, as described herein, consistently and reproducibly yielded a zone of reduced interstitial oxygen in the silicon wafer, and further, that the extent of said reduced interstitial oxygen zone could be controlled.

The thermal profile depicted in FIG. 2 first creates a melt region 300 at the top of the granular semiconductor material 200, then creates a melt region 310 extending through the entirety of the setter, and then creates a nucleation and growth region 400 where both liquid and a growing layer of polycrystalline layer coexist (i.e., at or about the melting temperature of the semiconductor material, in the case of silicon, about 1,415 degrees C.). Finally, there is an annealing region 500 where the temperature of the polycrystalline semiconductor shape 600 is reduced in a prescribed manner to effect stress relief. Any or all of the preheat, melting, growth and anneal thermal profiles for the granular powder and resultant shape can be achieved by appropriate placement of heating devices, cooling devices and/or insulation, a wide variety of which are well known to those of skill in the art. For example, heating can be accomplished using an infrared heater or using a line source, such as by optical focusing.

In the process design, the thermal characteristics of the setter play a key role in managing the melt and growth processes. In the melt region 300 in the thermal profile depicted in FIG. 2, it is preferred that the thermal conductivity of the setter be low to assure the efficient deployment of the energy being used to melt the granular semiconductor material 200. The thermal properties of the setter may be tailored to possess one or more strips of higher thermal conductivity. The thermal conductivity of the setter may alternatively or additionally be tailored to include regions which assist in defining nucleation sites to commence growth. This can be accomplished by locally placing thermal shunts in the setter. These shunts provide a thermal conduction path between the top and bottom of the setter, effecting a local path for removing heat of solidification, resulting in sites where nucleated growth occurs.

After the granular semiconductor material 200 has been deposited in the setter recess, it is transported through a thermal profile for melting, solidification and crystallization as described in our earlier patent, U.S. Pat. No. 6,207,891. In the grain growth process, the rate of grain growth is determined by the details of heat extraction from the melt and the grain size is determined by the nucleation density.

After leaving the nucleation and growth zone 400 of the thermal profile, the shape 600 moves into the annealing zone 500 of the thermal profile. In this zone the grown shape, still at approximately 1,400 degrees C. (in the case of silicon), is subjected to a linear temperature gradient along the direction of setter motion. The linear temperature profile tends to eliminate any buckling and cracking of the as grown shape, and minimizes the generation of dislocations. The grown shape may have generally any size, e.g., major surfaces having surface areas of 1,000 cm² or less, e.g., 500 cm² or less, and any thickness, e.g., between about 100 microns and 2 mm, more typically in the range of 350 to 1000 microns (although thickness can be reduced to reduce consumption of semiconductor material). After cool down, the finished wafer can be removed from the setter, e.g., by vacuum suction, and can be further fabricated, e.g., into solar cells.

The top-down grain growth process described above results in provision of a device-active region at the top of the shape which is crystallized from the semiconductor melt while the bottom of the shape next to the setter is still solid, thus minimizing any contamination of the top of the shape by the setter.

The pulling speed of the setters through the heating/cooling region can be any desired rate, depending on the length of the thermal treatment and the size of each zone within the region. For example, suitable speeds can be greater than about 100 cm/min, preferably about 250 cm/min or higher.

As noted above, each recess may be of a specifically desired shape and/or may have a specifically desired surface and/or edge topography for imparting to the wafers one or more desired surface feature and/or pattern and/or one or more desired internal feature.

For example, the recesses can each be of any desired overall shape, and the recesses dictate the shape of the resulting wafers. For example, as mentioned above, the recesses can provide for round wafers, square wafers, rectangular wafers, hexagonal wafers, triangular wafers, symmetrical or asymmetrical wafers, wafers in the shapes of letters, etc., and can, for example, provide for rounded corners on any such shapes which have corners. Such rounded corners (e.g., having radius of curvature in the range of from about 1 mm to about 20 mm) simplify handling (and make handling more safe) and assist in reducing breakage of the wafers during the fabricating of the wafers.

A variety of surface patterns and/or surface features can be imparted to the wafers by the surfaces of the recesses, e.g., a pattern of ridges and valleys for enhancing the optical and electrical properties of a solar cell made using the wafer, flattened areas for formation of contacts or buses, guide ridges and/or notches for indexing the wafer in a downstream process, surfaces or grooves for directing flow of metallizations, dopants, dielectric precursors, etc. which are later applied. That is, the recesses can be structured with a “negative pattern” including one or more ridges, valleys, cavities and/or protrusions so that the wafers have a corresponding “positive pattern” including ridges (where the recesses include valleys), valleys (where the recesses include ridges), protrusions (where the recesses include cavities) and/or cavities (where the recesses include protrusions) which facilitate application of a functional element on the wafer, e.g., by roll printing, screenprinting, vapor deposition, liquid phase epitaxy, dripping liquid into one or more cavities or grooves, etc. The ridges can provide raised areas to which another material (e.g., a metal, an insulator, a dopant etc.) can readily be selectively applied, or can provide boundaries for controlling the flow of such a material. Analogously, the valleys and/or cavities can provide low areas which can provide separation between areas of material applied to adjacent raised areas, or can provide channels or pools in which such a material can flow before being solidified. If necessary, after applying such a material, the surface(s) can be treated so as to remove any such applied material from the raised portions (or surrounding portions), leaving the applied material in only the channels or grooves (or cavities), separated by the raised portions (or surrounding portions).

For example, such patterning can be employed where there is a desire for a discontinuous back surface metallization (as well known in the solar-electric art, the back surface is the side of the solar cell which is opposite the surface which faces the light, e.g., sunlight), or a desire for one part of the back surface to be raised relative to other parts (e.g., raised silver stripes on an aluminum back surface), etc. Similarly, such patterning can assist in isolating p-type current bus bars from n-type current bus bars where both types of buses are provided on the back surface (i.e., an all back contact design) by providing a series of grooves and ridges, alternating ridges being electrically connected to the p-region and the n-region, and the grooves assisting in avoiding short circuits between the n-type current bus bars and the p-type current bus bars.

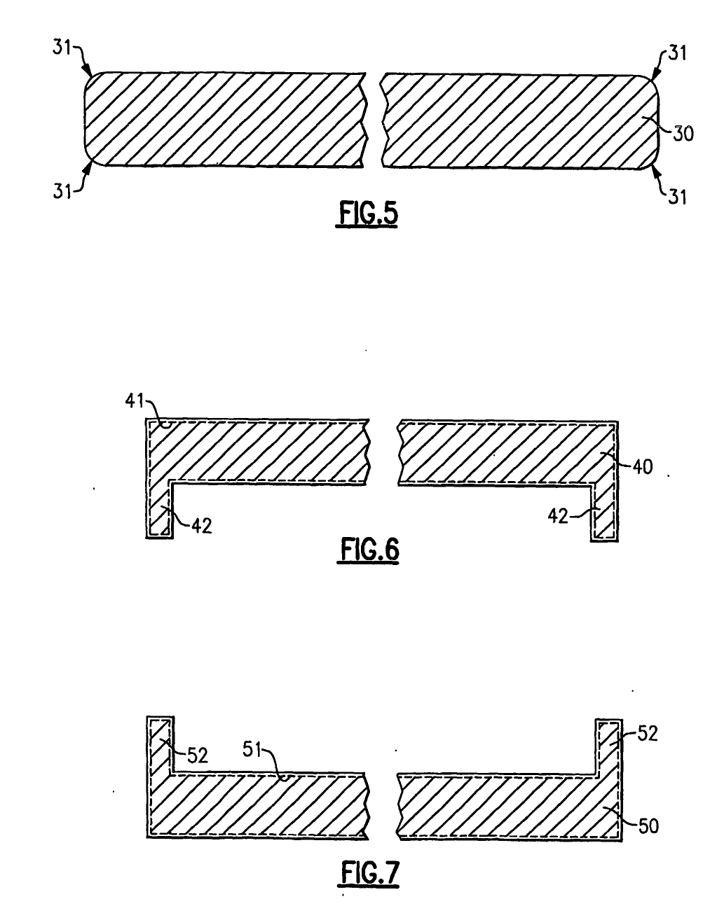

Another example of such patterning is where the front surface of the wafer (i.e., the surface which is designed to face the sun) is textured to provide improved optical and electrical properties. For example, it is well known that in many circumstances, by texturing the front surface of the wafer (e.g., a wafer 10 as depicted in cross-section in FIG. 3 which includes ridges 11 and valleys 12), a greater percentage of incident light can be absorbed, and the distance that electrons have to travel in order to reach the p-n junction can be reduced, resulting in greater overall power production. Ridges and valleys of any desired size (down to the resolution to which the setters are machined) can be employed, e.g., having amplitude of from about 50 to about 150 micrometers. If desired, such ridges and valleys (of a similar shape or a different shape) can be provided on both sides of the wafer (such a design can be especially advantageous with a thin wafer, particularly where the back surface is treated to be reflective, or where a reflective layer is applied). In addition, some of the ridges in such a textured surface can be flattened, (e.g., as depicted in FIG. 4, which depicts a wafer 20 in cross-section, including ridges 21 and valleys 22, as well as flattened ridges 23), in order to provide such improved optical and electrical properties, and to facilitate formation of contacts and/or bus bars on the front surface.

Similarly, the wafers can be structured so as to provide specifically desired thermal profile during thermal treatment, e.g., by providing a thickened region which will be heated to a temperature which is lower than if such region were thinner. For example, the edges of the wafer being fabricated can be structured to be thicker in order to pin the edges (i.e., to avoid edge retraction during cooling). In such a way, the thermal treatment can be specifically tailored for different regions of the wafer being fabricated.

A particularly preferred shape for a contact (especially a front surface contact) is one which is narrow but deep, in order to minimize the area over which the contact blocks light from being absorbed in the wafer, while maximizing the cross-sectional area of the contact perpendicular to the direction of current flow through the contact. For such a purpose, a wafer can be structured so as to have a groove of such a narrow and deep shape, which is later filled with the contact material (or partially filled with the contact material and then the remainder filled with semiconductor material in order to bury the contact within semiconductor material).

Similarly, the negative pattern in the recesses can be. structured so as to provide any desired topography on the wafer. Such topography includes the ability to provide wafers having rounded edges, which, similar to the provision of rounded corners, assists in safety and in reducing wafer breakage as well as damage to other equipment and materials which come into contact with the wafers. FIG. 5 is a sectional view depicting a wafer 30 which has rounded edges 31.

In addition, a variety of features can be imparted to wafers by the recesses. For example, each recess can include one or more protrusions projecting from the bottom of the recess, each protrusion resulting in the formation of a hole passing through part or all of the thickness of the wafer (see FIG. 9, discussed below). Such protrusions can be generally any suitable shape which projects upward from the bottom of a recess, and preferred shapes include generally frustoconical shapes and generally cylindrical shapes. Holes passing through part of all of the thickness of the wafer can be used, e.g., to transport electrons from one part of the wafer to another, for example, from the front surface to the back surface (i.e., to provide metal wrap-through metallization, which enables use of an all-back interconnect module packaging approach). Where a metal wrap through metallization is employed, the size of busbars on the front surface of the wafer can be reduced or the front surface busbars can be eliminated, if desired, e.g., to increase light collection area.

In many circumstances, a structure formed on one side of the wafer is visible in the form of modified grain structure (e.g., larger or smaller grains) on the opposite side, depending, e.g., on the depth of structuring (e.g., typically if greater than about 75 micrometers), the temperature profile to which the wafer is subjected, the thickness of the wafer and the nature of the semiconductor material used to make the wafer. Such phenomena can be used for a variety of design purposes, if desired. It should be noted here that structures formed in the wafers are not required to be symmetrical. In fact, it may be desirable to have non-symmetrical structures of various or varying geometries.

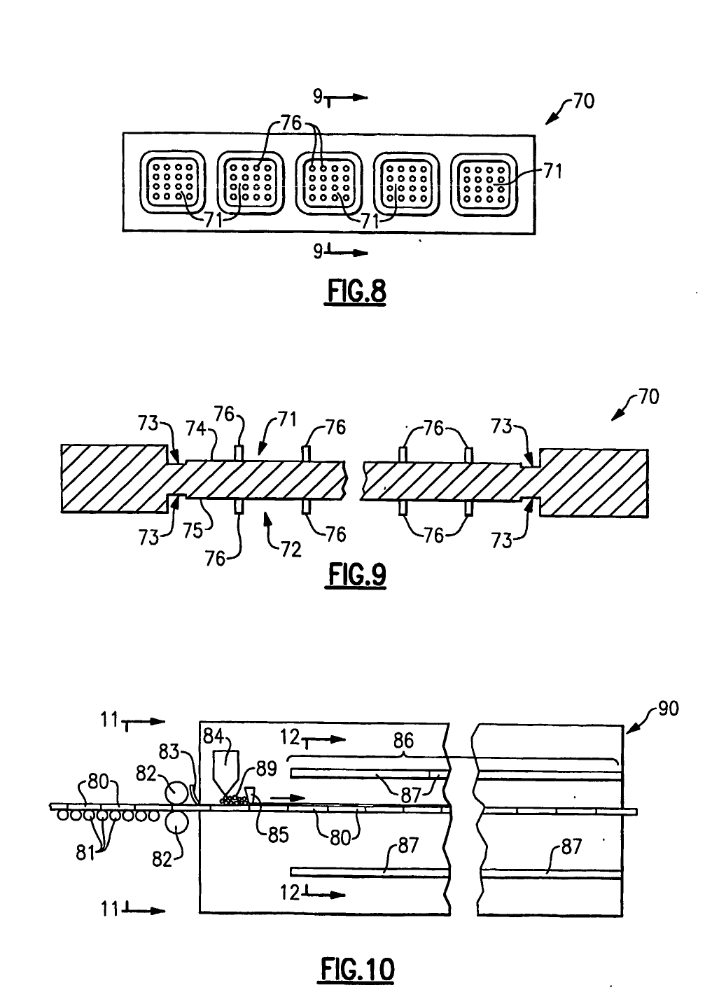

Another feature which can be provided in the wafers by the shape of the recesses are junction isolation ridges. As is well known, for instance, a typical process involves applying an n-dopant to a previously p-doped wafer (or sometimes applying a p-dopant to a previously n-doped wafer) to provide an n-doped region and a p-n junction. Typically, in such a treatment, a p-n junction is formed around the entire wafer, a slight distance (typically less than a micrometer) below the surface of the wafer. For efficient use, it is desirable for the n-region on the front surface to be electrically isolated (i.e., to be not electrically connected) to any high conductivity region on the back surface, and it is most desirable for the p-n junction to consist of only a substantially flat region just below the front surface of the wafer. In the past, the n-doped layer on the sides of the wafers has typically been removed by eliminating the sides of the wafers, e.g., by dicing them, by physical abrasion, by chemically etching or by plasma etching. Protrusions (referred to herein as junction isolation ridges) can be formed along edges of the wafers (as a result of cavities provided in the recesses), through which the p-n junction, when formed, will pass, and the regions of the p-n junctions on the back surface of the wafer can be isolated from the p-n junction just under the front surface by snapping off the junction isolation ridges. For example, FIGS. 6 and 7 depict sectional views of two embodiments of wafers which exemplify such provision of junction isolation ridges. In FIG. 6, there is shown a sectional view of a wafer 40 having a p-n junction 41 and a junction isolation ridge 42 (formed on the back surface of the wafer 40) which, when snapped off, isolates the n-region on the front surface of the wafer from the high conductivity region on the back surface of the wafer. In FIG. 7, there is shown a sectional view of a wafer 50 having a p-n junction 51 and a junction isolation ridge 52 (formed on the front surface of the wafer 50) which, when snapped off, isolates the n-region on the front surface of the wafer from the remainder of the p-n junction. In addition, the p-n junction on the back surface of the wafer may be eliminated as a result of applying a back surface highly conductive region, e.g., of aluminum, as is well known in the art, which, in connection with the semiconductor element shown in FIG. 7, provides a wafer in which the p-n junction consists of only a substantially flat region just below the front surface of the wafer.

As mentioned above, another feature which can readily be provided to wafers through structuring of recesses in accordance with the present invention are edge regions on the wafer which are thicker than the remainder of the wafer, e.g., by about 40 to 100 micrometers for a wafer which is about 900 micrometers thick. By providing thicker edge regions in the recesses, as the semiconductor material passes through the zones of the heating/cooling region where the semiconductor material is heated, due to the greater thickness, the semiconductor material in the edges of the recesses will reach a lower temperature and solidify before the semiconductor material in the other parts of the recesses, thereby providing “pinning” of the edges; i.e., avoiding retraction of the edges of the wafer during cooling.

Preferably, when making wafers for use in production of solar cells, the surface of the wafer which was formed in contact with the bottom region of a recess is the surface which faces away from the incident light (i.e., at least part of it becomes at least part of the back surface of the solar cell), and the opposite surface of the wafer faces the incident light (i.e., at least part of it becomes at least part of the front surface of the solar cell). The topography of the surface of the wafer formed in contact with the bottom region of the recess can readily be controlled by appropriate structuring of the recess. Similarly, the topography of the edges of the wafer can be controlled by appropriate structuring of the recess. Also, as indicated above, holes or cavities in the wafer extending from any part of the wafer which is formed in contact with the recess can be provided by protrusions from the recess. In order to structure the remaining surface of the semiconductor material (i.e., the surface opposite the surface formed in contact with the recess), at least part of which, in the orientation described in this paragraph, becomes at least part of the front surface of the solar cell, a setter lid can be provided which is positioned above the semiconductor material in the recess (e.g., the setter lid can be placed on top of semiconductor material positioned in the recess, so that as the semiconductor material melts and voids between the solid particles disappear so that the top surface of the semiconductor material lowers, the lid lowers with it), or one or more scraper bars, or texturing or molding elements can be provided which come into contact with the semiconductor material on a side of the semiconductor material which is opposite to the side of the semiconductor material which is in contact with the bottom region of the recess (e.g., such scraper bar, or texturing or molding elements can be lowered into the semiconductor material, if necessary, e.g., if the melting of the semiconductor material causes the top surface of the semiconductor material to descend to below the top of the setter). Preferably, shortly after the top surface of the semiconductor material is structured, it is solidified in order to keep such structure. Such a setter lid also serves to protect the wafer being fabricated from impurities in the area which might otherwise migrate into the semiconductor material.

Alternatively (or additionally), the wafer can be fabricated in an inverted orientation, with the surface which is to become at least part of the front surface of the solar cell being in contact with the bottom region of the recess, and directional solidification being conducted from the bottom up. In such a case, the heating/cooling profile could be modified so as to compensate for the inverted orientation, and to compensate for any other thermal factors, e.g., that the heat from the heaters below the setters must pass through the setters before reaching the semiconductor material. In addition, in such a case, potential contamination from the setter and/or any release agent applied to the setter needs to be addressed and/or taken into consideration, because the crystal structure of the front surface has profound effects on the overall properties of the solar cell.

In addition, as mentioned above, the sidewalls of the recesses in the setters can be shaped so as to have a taper, i.e., the cross-sectional area of the recess increases as a distance from the bottom region of the recess increases, such that expansion of the silicon upon solidification merely tends to push the shapes within the recesses upward a slight distance. Any suitable degree of taper can be employed, and the degree of taper can vary around the sidewall of the recess in the lateral and/or vertical dimension. An example of a suitable degree of taper can be about 15 degrees.

The wafer is then removed from the setters, e.g., using vacuum suction. If desired, such a wafer can be sent through the heating/cooling region a second time (or more times). Doing so can provide even better structural quality of the semiconductor material in the wafer. Such refabricating can be accomplished without excessive stress on the wafer and without affecting yield. The completed wafer does not need to be sized.

The following is a description of a specific preferred embodiment of a setter. Referring to FIG. 8, the top surface of the setter 70 has a plurality of recesses 71 therein. The setter 70 also has a plurality of recesses in its bottom surface, the recesses in the bottom surface being substantially mirror images of the recesses in the top surface. The setter 70 also has a plurality of protrusions 76 extending from the recesses 71. FIG. 9 is a sectional view along line IX-IX of FIG. 8. FIG. 9 shows the setter 70, including a recess 71 on the top surface of the setter 70 and a recess 72 on the bottom surface of the setter 70. As shown in FIG. 9, a perimeter 73 of each recess 71 and 72 is slightly deeper than the remainder of each recess. FIG. 9 also shows a bottom region 74 of the recess 71 and a bottom region of the recess 75. FIG. 9 further shows protrusions 76 extending from each of the recesses 71 and 72.

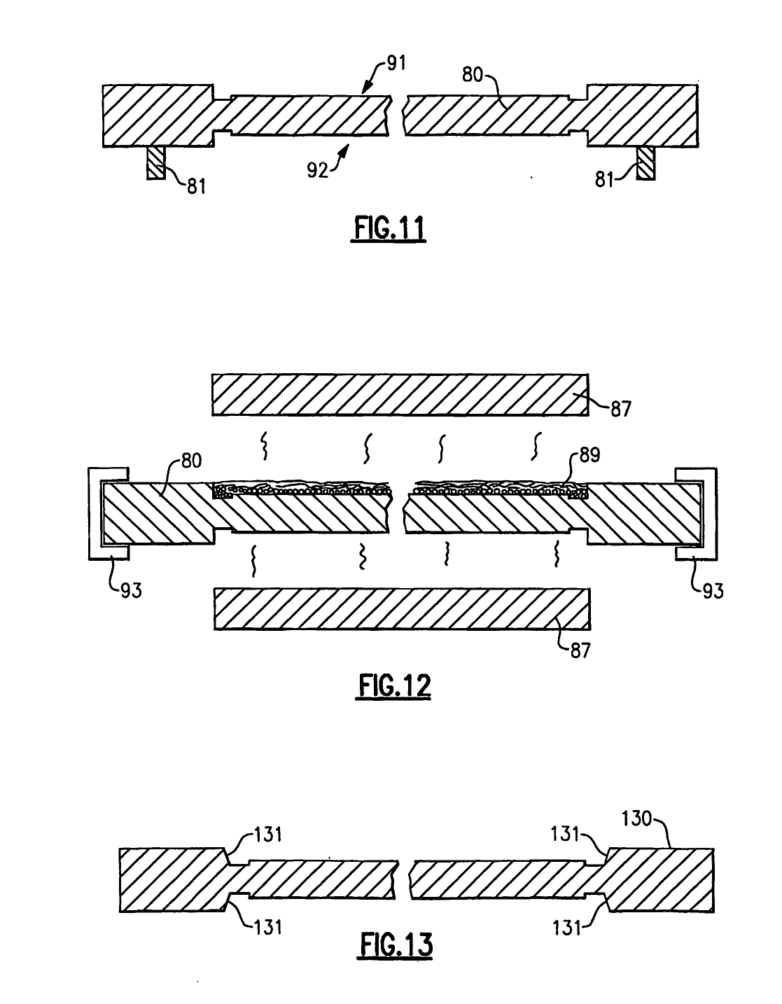

The following is a description of a specific fabrication apparatus which can be used to fabricate a wafer. FIG. 10 is a schematic view showing some of the elements of this apparatus. Referring to FIG. 10, setters 80 are fed along rollers 81 which push the setters toward a pair of pinch rollers 82. The pinch rollers 82 push the setters through the entire fabrication apparatus 90, so that they pass under a hopper 84, under a doctor blade 85, through a heating/cooling region 86 including a plurality of thermal treatment devices 87, and then out of the fabrication apparatus 90, after which the setters are stored until they are needed again. The pinch rollers 82 push the setters 80 at a rate which is slower than the rate that the powered rollers 81 push the setters toward the pinch rollers 82, in order to ensure that the setters 80 proceed through the fabrication apparatus 90 substantially end to end. FIG. 11 is a sectional view along line XI-XI, depicting a setter 80 riding along a pair of rollers 81, the view showing a top recess 91 and a bottom recess 92 of the setter 80.

An inert atmosphere is preferably maintained within the fabrication apparatus 90. Preferably, the interior of the fabrication apparatus is sealed in order to assist in preventing the inert materials from escaping from the fabrication apparatus 90.

The setters 80 then pass under a hopper 84 which deposits a desired quantity of semiconductor material 89 (together with any desired additives) into the recesses 91 of the setter which are facing upward. The setters 80 then pass under the doctor blade 85 which smooths the semiconductor material 89 into the recesses 91.

The setters 80, along with the semiconductor material 89, are then subjected to a thermal treatment as they pass through the heating/cooling region 86. A plurality of thermal treatment devices 87 are arranged along the path of the setters 80 above and below the setters 80. Each thermal treatment device 87 can be separately controlled, so as to heat or cool the semiconductor material 89 from above or below, thereby enabling any desired thermal profile (as discussed above) to be carried out. FIG. 12 is a sectional view showing a setter 80 as it is passing through one particular zone within the fabrication apparatus 90. Referring to FIG. 12, the setters 80 pass between a thermal treatment device 87 positioned above the path of the setters and a thermal treatment device 87 positioned below the path of the setters, and the setters 80 are guided by a pair of side supports 93 as they pass through the fabrication apparatus 90.

After the setters 80 exit from the fabrication apparatus 90, a wafer is removed from each recess, e.g., by use of a vacuum wand. The setters 80 are stored until they are reused.

FIG. 13 is a sectional view of a setter 130 having recesses which have a slight taper in their sidewalls 131.

Any two or more structural parts of the apparatus can be integrated; any structural part of the apparatus can be provided in two or more parts (which are held together, if necessary). Similarly, any two or more functions can be conducted simultaneously, and/or any function can be conducted in a series of steps.

1. A semiconductor element comprising:
a structure comprising at least one semiconductor material, said structure having a first major surface, a second major surface and an edge region, said first major surface being opposite said second major surface, and said edge region comprising at least one surface between said first major surface and said second major surface,
said structure comprising at least one zone of reduced oxygen concentration, said zone of reduced oxygen concentration having an interstitial oxygen concentration of not greater than 3×10¹⁷ oxygen atoms/cm³, said zone of reduced oxygen concentration including said first major surface and all points in said structure which are within 75 microns of said first major surface.

2. A semiconductor element as recited in claim 1, wherein said zone of reduced oxygen concentration includes said first major surface and all points in said structure which are within 100 microns of said first major surface.

3. A semiconductor element as recited in claim 1, wherein said zone of reduced oxygen concentration includes said first major surface and all points in said structure which are within 125 microns of said first major surface.

4. A semiconductor element as recited in claim 1, wherein said zone of reduced oxygen concentration includes said first major surface and all points in said structure which are within 150 of said first major surface.

5. A semiconductor element as recited in claim 1, wherein said zone of reduced oxygen concentration includes said first major surface and all points in said structure which are within 175 microns of said first major surface.

6. A semiconductor element as recited in claim 1, wherein said zone of reduced oxygen concentration includes said first major surface and all points in said structure which are within 200 microns of said first major surface.

7. A semiconductor element as recited in claim 1, wherein said zone of reduced oxygen concentration includes at least one member selected from the group consisting of at least 10¹⁵ or more atoms/cm³ of nitrogen, at least 10¹⁷ or more atoms/cm³ of carbon, and one or more transition metal elements in a total amount of at least 10¹⁶ or more atoms/cm³.

8. A semiconductor element as recited in claim 1, wherein said semiconductor element has at least one hole extending from said first major surface to said second major surface.

9. A semiconductor element as recited in claim 1, wherein at least one of said major surfaces of said semiconductor element has at least one ridge.

10. A semiconductor element as recited in claim 9, wherein said at least one ridge substantially extends around a perimeter of said major surface of said semiconductor element.

11. A semiconductor element as recited in claim 1, wherein at least one of said major surfaces of said semiconductor element has at least one valley.

12. A semiconductor element as recited in claim 1, wherein a substantial perimeter of at least one of said major surfaces of said semiconductor element is thicker than adjacent regions of said semiconductor element.

13. A semiconductor element as recited in claim 1, wherein said semiconductor element has a thickness defined from said first major surface to said second major surface of about 600 micrometers or less.

14. A semiconductor element as recited in claim 1, wherein at least part of said edge region is rounded.

15. A semiconductor element as recited in claim 1, wherein at least part of said edge region is not perpendicular to said first and second major surfaces.

16. A semiconductor element as recited in claim 1, wherein an area of said first major surface is not greater than about 1000 cm².

17. A photovoltaic cell comprising at least one semiconductor element as recited in claim 1.

18. A photovoltaic cell comprising at least one semiconductor element as recited in claim 1, wherein said photovoltaic cell is a metal wrap through solar cell.
